(19) United States
(12) Patent Application Publication
(10) Pub. No.: US 2015/0059477 A1
(43) Pub. Date: Mar. 5, 2015

(54) ACCELERATION SENSOR

(71) Applicant: SAMSUNG ELECTRO-MECHANICS CO., LTD., Suwon-Si (KR)

(72) Inventors: Jong Woon Kim, Suwon-Si (KR); Sung Jun Lee, Suwon-Si (KR); Chang Hyun Lim, Suwon-Si (KR)

(73) Assignee: SAMSUNG ELECTRO-MECHANICS CO., LTD., Suwon-Si (KR)

(21) Appl. No.: 14/462,359

(22) Filed: Aug. 18, 2014

(30) Foreign Application Priority Data
Aug. 29, 2013 (KR) 10-2013-0103025

(51) Int. Cl. G01P 15/12; H01L 41/113

(52) U.S. Cl. CPC G01P 15/123; H01L 41/1132
USPC 73/514.33

(57) ABSTRACT

Disclosed herein is an acceleration sensor including: a mass; a flexible beam on which an electrode or a piezoresistive element is disposed and the mass is coupled; and a support part connecting to and supporting the flexible beam and having therein a stress isolating slit facing the mass, wherein the mass, the flexible beam and the support part are formed by coupling first and second substrates, wherein the first substrate has a first masking pattern formed thereon corresponding to the flexible beam, the mass and the support part and the second substrate has a second masking pattern formed thereon corresponding to the mass and the support part.

### CROSS REFERENCE TO RELATED APPLICATION

This application claims the benefit of Korean Patent Application No. 10-2013-0103025, filed on Aug. 29, 2013, entitled “Acceleration Sensor,” which is hereby incorporated by reference in its entirety into this application.

### BACKGROUND OF THE INVENTION

1. Technical Field

The present invention relates to an acceleration sensor.

2. Description of the Related Art

In general, an inertial sensor is being variously used in automobiles, airplanes, mobile communication terminals, toys and the like. It includes a 3-axis acceleration sensor and an angular velocity sensor to measure acceleration and angular velocity on x-, y-, and z-axes. Further, it is being developed to have high performance and to be small in order to detect minimal acceleration.

The acceleration sensor included in the inertial sensor includes a technical feature to convert motions of a mass and a flexible beam into an electric signal. The types of acceleration sensors include a piezoresistive type in which the motion of the mass is detected from a change in resistance of a piezo element located on a flexible beam, and a capacitive type in which the motions of the mass is detected from a change in capacitance between fixed electrodes.

The piezoresistive type uses an element having a resistance varying by stress. For example, the resistance increases where tensile stress is distributed and decreases where compressive stress is distributed.

Further, in the piezoresistive type acceleration sensors according to the prior art, including one disclosed in Patent Document below, the area of the beam is reduced in order to increase sensitivity, so that it is vulnerable to shock, and especially reliability on a fall is lowered.

Further, in order to increase sensitivity, it is preferred to locate a piezoresistive element at an end of the flexible part where stress is concentrated. However, if there is a variation in the angle of a sidewall during the etching process for forming the flexible part, the distance between the end of the flexible part and the piezo element is changed, so that sensitivity is lowered. Moreover, the thickness of the mass has to be thick in order to increase sensitivity, whereas a variation in the angle of the sidewall becomes greater as the etching depth becomes deeper.

Additionally, if stress, a change in temperature, mechanical shock and vibration from outside and the like are applied to a beam-like flexible part in an acceleration sensor, rigidity is changed as tension changes, and thus sensitivity is changed. Excessive tension causes the beam to be broken. Moreover, since a stress isolating beam has a narrow width to isolate external weight, when the thickness of the stress isolating beam and that of the mass is the same, it is difficult to form a desired width due to a narrow variation in the angle of the sidewall for etching. In the worst case, the flexible part and the stress isolating beam are separated.

### PRIOR ART DOCUMENT

### [Patent Document]

(Patent Document 1) US 2006/0156818 A

### SUMMARY OF THE INVENTION

The present invention has been made in an effort to provide an acceleration sensor which maximally isolates external weight by way of lowering rigidity of a stress isolating beam.

Further, the present invention has been made in an effort to provide an acceleration sensor capable of improving sensitivity and reducing sensitivity variations by way of configuring the acceleration sensor in multiple layers having first and second substrates to form components through first and second masking patterns, thereby forming a flexible beam having a shallow etching depth and locating a piezo element at the optimum position.

According to a first preferred embodiment of the present invention, there is provided an acceleration sensor including: a mass; a flexible beam on which an electrode or a piezoresistive element is disposed and the mass is coupled; and a support part connecting to and supporting the flexible beam and having therein a stress isolating slit facing the mass, wherein the mass, the flexible beam and the support part are formed by coupling first and second substrates, wherein the first substrate has a first masking pattern formed thereon corresponding to the flexible beam, the mass and the support part and the second substrate has a second masking pattern formed thereon corresponding to the mass and the support part.

The support part may include therein a stress isolating beam by the presence of the stress isolating slit, and the stress isolating beam may be formed with the first substrate.

The stress isolating beam may include: a membrane part connected to the flexible beam; and a stress isolating part perpendicularly connected to the membrane part.

A coupling portion of the stress isolating part coupled with the membrane part may be smaller than the membrane part in area.

The stress isolating part may include: a beam part perpendicularly coupled with the membrane part; and a protruding part protruding from the beam part toward the flexible beam.

The flexible beam may be formed with the first substrate.

The mass may include: a first mass formed with the first substrate; and a second mass formed with the second substrate.

The first masking pattern may be formed on a surface of the first mass facing the second mass, and the second masking pattern may be formed on the second mass.

The first masking pattern may be larger than the second masking pattern in area.

The support part may include: a first support part formed with the first substrate; and a second support part formed with the second substrate.

The first masking pattern may be formed between the first support part and the second support part, and the second masking pattern may be formed on the second support part.

The first masking pattern may be larger than the second masking pattern in area.

The second support part may be smaller than the first support part in area.

The first masking pattern may face the second substrate.

The acceleration sensor may further include a lower cover coupled with one surface of the support part, and the second masking pattern may face the lower cover.

According to a second preferred embodiment of the present invention, there is provided an acceleration sensor including: a mass; a flexible beam on which an electrode or a piezoresistive element is disposed and the mass is coupled; and a support part connecting to and supporting the flexible beam and having therein a stress isolating slit facing the mass, wherein the mass, the flexible beam and the support part are formed by coupling first and second substrates, wherein the first substrate has a first masking pattern formed thereon corresponding to the flexible beam, the mass and the support part.

The support part may include therein a stress isolating beam by the presence of the stress isolating slit, and the stress isolating beam may be formed with the first substrate.

The flexible beam may be formed with the first substrate.

The mass may include: a first mass formed with the first substrate; and a second mass formed with the second substrate.

The first masking pattern may be formed between the first mass and the second mass, and the first mass is larger than the second mass in area.

The support part may include: a first support part formed with the first substrate; and a second support part formed with the second substrate, wherein the first masking pattern is formed between the first support part and the second support part, wherein the first support part is larger than the second support part in area.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a plan view schematically showing an acceleration sensor according to a preferred embodiment of the present invention;

FIG. 2 is a simplified cross-sectional view of the acceleration sensor taken along line A-A in FIG. 1;

FIG. 3 is a simplified cross-sectional view of the acceleration sensor taken along line B-B in FIG. 1;

FIG. 4A is an enlarged view of a stress isolating beam which is shown as portion C in FIG. 1;

FIG. 4B is an enlarged view of a stress isolating beam which is shown as portion D in FIG. 2;

FIG. 5A is a simplified enlarged plan view of a stress isolating beam according to another preferred embodiment;

FIG. 5B is a simplified enlarged cross-sectional view of the stress isolating beam according to the another preferred embodiment;

FIG. 6A is a simplified enlarged plan view of a stress isolating beam according to yet another preferred embodiment;

FIG. 6B is a simplified enlarged cross-sectional view of the stress isolating beam according to the yet another preferred embodiment;

FIG. 6C is a simplified enlarged perspective view of the stress isolating beam according to the yet another preferred embodiment; and

FIG. 7 is a simplified cross-sectional view of an acceleration sensor according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

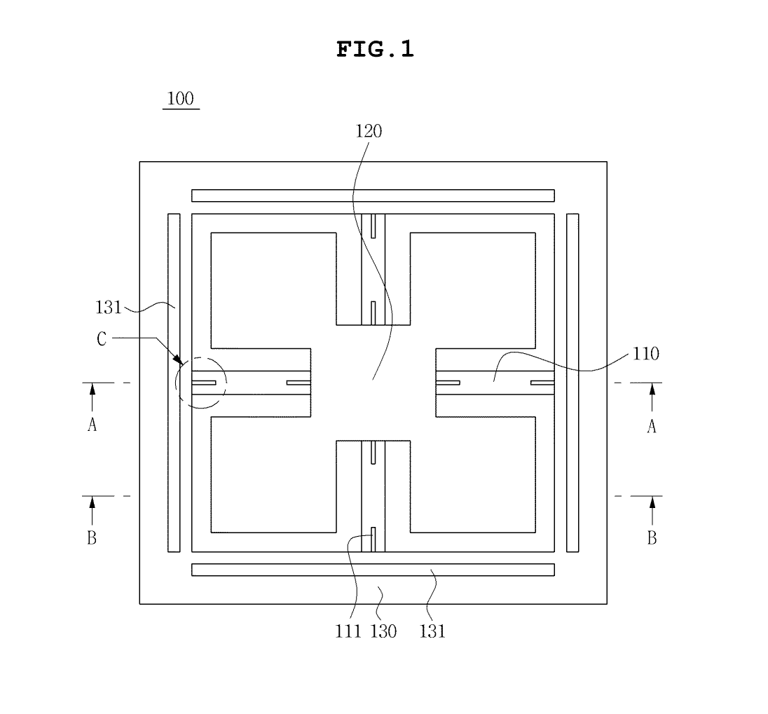

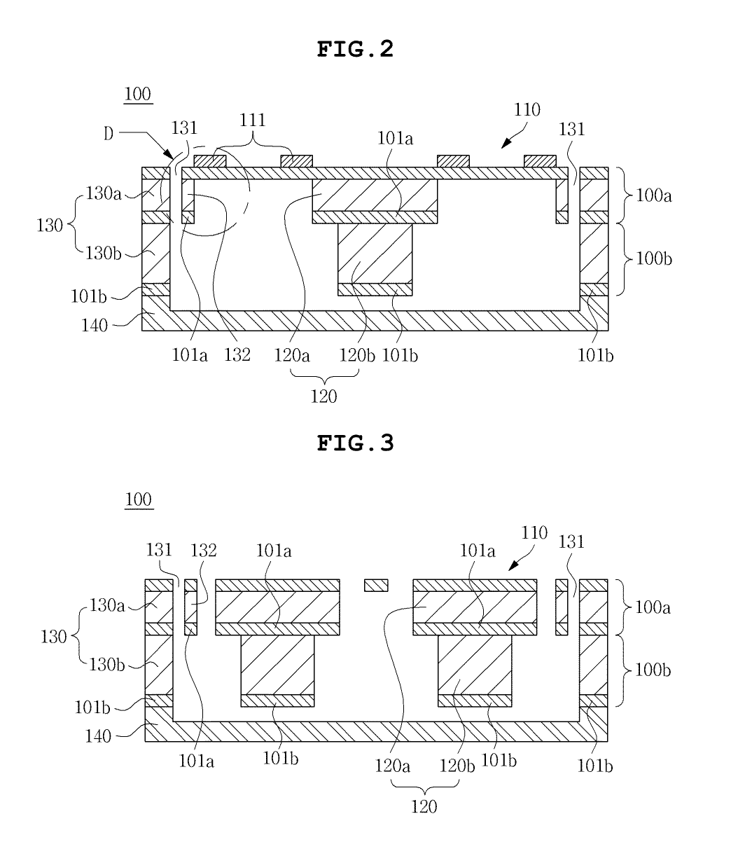

FIG. 1 is a plan view schematically showing an acceleration sensor according to a preferred embodiment of the present invention, FIG. 2 is a schematic cross-sectional view of the acceleration sensor taken along line A-A in FIG. 1, and FIG. 3 is a schematic cross-sectional view of the acceleration sensor taken along line B-B in FIG. 1.

As shown, an acceleration sensor 100 includes a flexible beam 110, a mass 120 and a support part 130.

Specifically, the acceleration sensor 100 is formed by coupling a first substrate 100a with a second substrate 100b and performing etching in a predetermined pattern.

To this end, the first substrate 100a has a first masking pattern 101a corresponding to the flexible beam 110, the mass 120 and the support part 130 formed thereon, and the second substrate 100b has a second masking pattern 101b corresponding to the mass 120 and the support part 130 formed thereon.

In addition, the support part 130 has a stress isolating slit 131 formed therein, and the stress isolating beam 132 is formed by the presence of the stress isolating slit 131.

Further, the components of the acceleration sensor 100 may be formed with the first substrate 100a only or with the first substrate 100a and the second substrate 100b.

That is, the flexible beam 110 is formed with the first substrate 100a, and the mass 120 includes the first mass 120a formed with the first substrate 100a and the second mass 120b formed with the second substrate 100b.

In addition, the first masking pattern 101a is formed on one surface of the first mass 120a facing the second mass 120b, and the second masking pattern 101b is formed on the second mass 120b.

Then, the first masking pattern 101a has a larger area than the second masking pattern 101b, and thus the first mass has a larger area than the second mass.

This is resulted from the etching order, in which etching is done using the second masking pattern 101b first and then using the first masking pattern 101a.

Further, the support part 130 includes a first support part 130a formed with the first substrate 100a and a second support part 130b formed with the second substrate 100b.

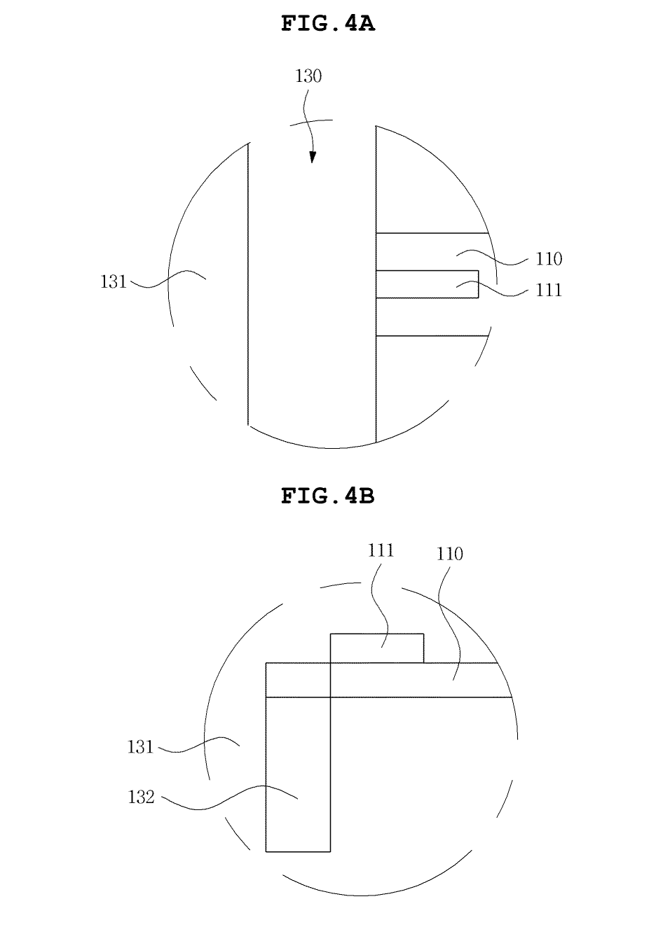

In addition to FIGS. 2 and 3, as shown in FIGS. 4A and 4B, the stress isolating slit 131 is formed in the first support part 130a and the stress isolating beam 132 is formed by the presence of the stress isolating slit 131. That is, the stress isolating beam 132 is formed with the first substrate 100a.

Further, the first masking pattern is formed between the first support part 130a and the second support part 130b, and the second masking pattern is formed on the second support part 130b. Then, the first masking pattern 101a has a larger area than the second masking pattern 101b. Accordingly, the second support part 130b has a smaller area than the first support part 130a.

Further, on one surface of the first substrate 100a, the first masking pattern 101a for forming the flexible beam 110, the first mass 120a and the first support part 130a is formed facing the second substrate 100b.

Further, on one surface of the second substrate 100b, the second masking pattern 101b for forming the second mass 120b and the second support part 130b is formed facing a lower cover 140.

As described above, the acceleration sensor 100 according to the present invention is configured in multiple layers having the first substrate 100a and the second substrate 100b to form components through the first masking pattern 101a and the second masking pattern 101b, respectively, thereby forming a flexible beam having a shallow etching depth and maintaining a piezo element 111 at the optimum position. Therefore, sensitivity can be improved and variation in sensitivity can be reduced, as well as maximally isolating external weight.

Hereinafter, components of the acceleration sensor according to the preferred embodiment of the present invention and the relationship therebetween will be described in detail.

More specifically, the flexible beam 110 has a plate shape and is a flexible substrate such as an elastic membrane or a beam to allow the mass 120 to be displaced.

In addition, on one surface of the flexible beam 110, a piezoresistive element 111 is formed.

Further, the mass 120 is coupled with one surface of the flexible beam 110 and is displaced by inertial force, external force, Coriolis force, driving force and the like.

Additionally, the support part 130 is coupled with one surface of the flexible beam and supports the mass 120 such that it is floated so as to be displaced.

Here, the mass 120 is located at the center of the flexible beam 110, the support part 130 has a hollow portion, such that the mass 120 is located in the hollow portion so that it is displaceable. Further, the support part 130 is located along the edge of the flexible beam 110 so as to give space for the mass 120 to be displaced.

Further, the mass 120 may have a square pillar shape, and the support part 130 may have a cylinder or a square pillar shape. Further, the shapes of the mass 120 and the support part 130 are not limited thereto but they may have any shape known in the art.

In the preferred embodiment of the present invention in which an inertial sensor is implemented as the acceleration sensor, when external force is applied, the mass 120 is moved by a moment generated by the external force and the resistance value of the piezoresistive element 111 on the flexible beam 110 is changed by the displacement of the mass 120. Then, acceleration is calculated by detecting the resistance value.

Further, the acceleration sensor 100 according to the preferred embodiment of the present invention may further include a lower cover 140 coupled with one surface of the support part 130 so as to cover the mass 120.

Further, the acceleration sensor 100 according to the preferred embodiment of the present invention may further include an upper cover (not shown) coupled with one surface of the support part 130 so as to cover the piezoresistive element 111.

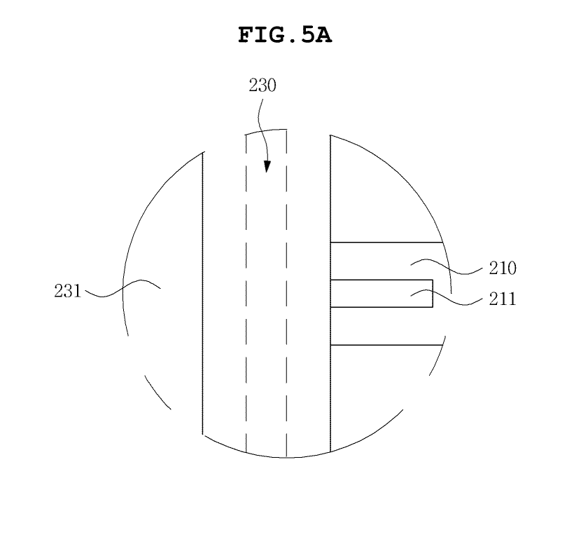

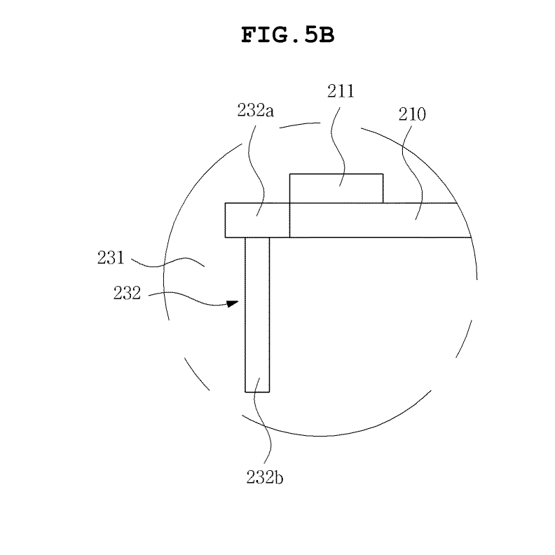

FIG. 5A is a simplified enlarged plan view of a stress isolating beam according to another preferred embodiment; and FIG. 5B is a simplified enlarged cross-sectional view of the stress isolating beam according to the another preferred embodiment.

As shown, the support part 230 has a slit 231 formed therein, and stress isolating beam 232 are formed by the presence of the slit 231.

The stress isolating beam 232 includes a membrane part 232a and a stress isolating part 232b. The membrane part 232a is connected to the flexible beam 210 while the stress isolating part 232b is perpendicularly connected to the membrane part 232a.

Then, the coupling portion of the stress isolating part 232b coupled with the membrane part 232a has a smaller area than the membrane part 232a.

That is, the stress isolating part 232b of the stress isolating beam 232 according to the another preferred embodiment of the present invention has a smaller area than the stress isolating beam 132 according to the preferred embodiment shown in FIG. 4B, thereby minimizing the rigidity of the stress isolating beam.

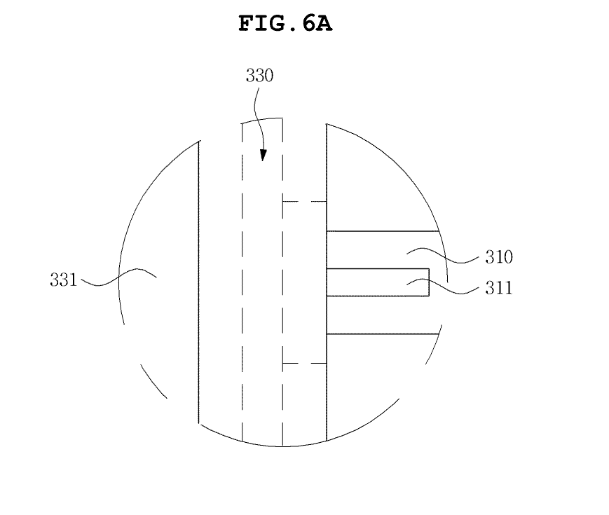

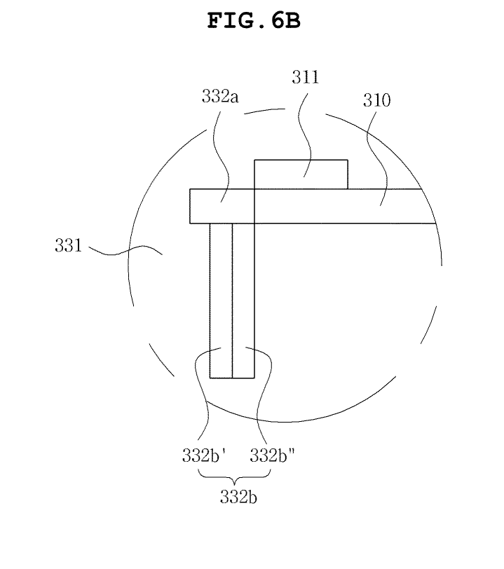

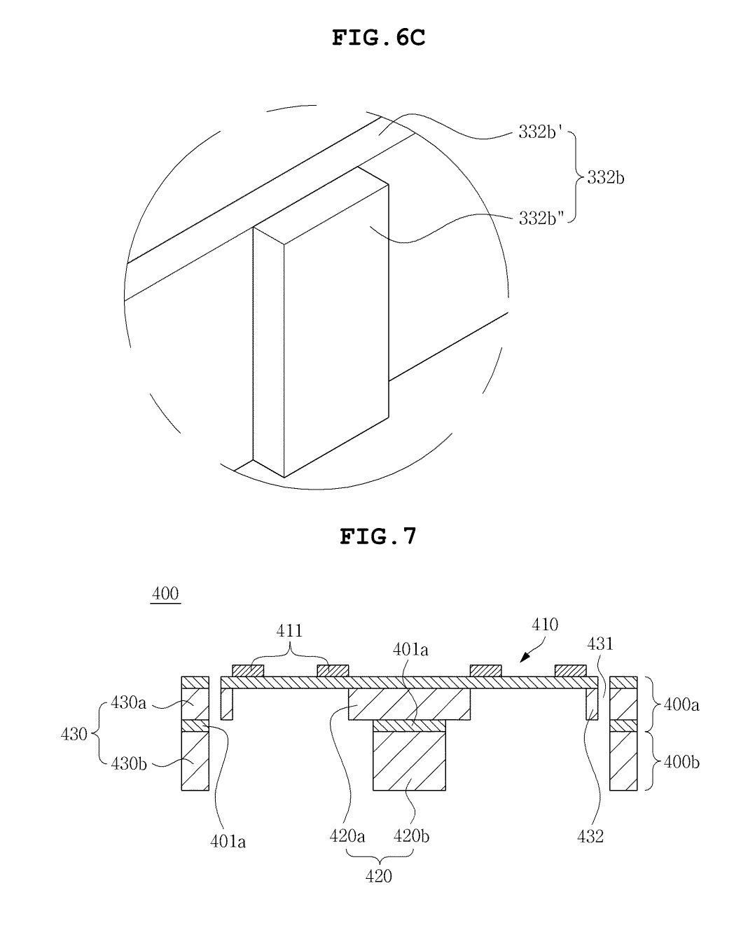

FIG. 6A is a simplified enlarged plan view of a stress isolating beam according to yet another preferred embodiment; FIG. 6B is a simplified enlarged cross-sectional view of the stress isolating beam according to the yet another preferred embodiment; and FIG. 6C is a simplified enlarged perspective view of the stress isolating beam according to the yet another preferred embodiment.

As shown, the support part 330 has a slit 331 formed therein, and a stress isolating beam 332 is formed by the presence of the slit 331.

The stress isolating beam 332 includes a membrane part 332a and a stress isolating part 332b. The membrane part 332a is connected to the flexible beam 310, and the stress isolating part 332b is perpendicularly connected to the membrane part 332a.

Further, the stress isolating part 332b includes a beam part 332b′ and a protruding part 332b″.

Then, the coupling portion of the stress isolating part 332b coupled with the membrane part 332a has a smaller area than the membrane part 332a.

That is, the stress isolating beam 332 according to the yet another preferred embodiment of the present invention has a smaller area than the stress isolating beam 132 according to the preferred embodiment shown in FIG. 4B, thereby minimizing the rigidity of the stress isolating beam as well as maximizing the sensitivity by locating a piezoresistive element 311 at an end of a flexible part.

FIG. 7 is a simplified cross-sectional view of an acceleration sensor according to another preferred embodiment of the present invention. Compared to the acceleration sensor according to the preferred embodiment shown in FIG. 1, the acceleration sensor shown in FIG. 7 has no remaining masking pattern exposed to the outside.

As shown, an acceleration sensor 400 includes a flexible beam 410, a mass 420 and a support part 430.

Specifically, the acceleration sensor 400 is formed by coupling a first substrate 400a with a second substrate 400b and performing etching in a predetermined pattern.

To this end, on one surface of the first substrate 400a, a first masking pattern 401a corresponding to the flexible beam 410, the mass 420 and the support part 430 is formed.

In addition, the support part 430 has a stress isolating slit 431 formed therein, and the stress isolating beam 432 is formed by the presence of the stress isolating slit 431.

Further, the components of the acceleration sensor 400 may be formed with the first substrate 400a only or with the first substrate 400a and the second substrate 400b.

That is, the flexible beam 410 is formed with the first substrate 400a, and the mass 420 includes the first mass 420a formed with the first substrate 400a and the second mass 420b formed with the second substrate 400b.

In addition, the first masking pattern 401a is formed between the first mass 420a and the second mass 420b.

Then, the first mass 420a has a larger area than the second mass 420b.

Further, the support part 430 includes a first support part 430a formed with the first substrate 400a and a second support part 430b formed with the second substrate 400b.

In addition, the first support part 430a has a stress isolating slit 431 formed therein, and the stress isolating beam 432 is formed by the presence of the stress isolating slit 431. That is, the stress isolating beam 432 is formed with the first substrate 400a.

In addition, the first masking pattern 401a is formed between the first support part 430a and the second support part 430b.

Then, the first support part 430a has a larger area than the second support part 430b.

Further, on one surface of the second substrate 400b, a second masking pattern (not shown) for forming the second mass 420b and the second support part 430b is formed facing a lower cover (not shown).

The first masking pattern 401a and the second masking pattern thus configured and exposed to the outside are further etched, to produce the acceleration sensor 400 shown in FIG. 4.

Further, in the acceleration sensor 400 according to another preferred embodiment of the present invention, the support part 430 may be implemented to form the stress isolating beam shown in FIGS. 5 and 6.

As set forth above, according to the embodiments of the present invention, rigidity of a stress isolating beam can be lowered so that external weight is maximally isolated. Further, sensitivity can be improved and sensitivity variations can be lowered by way of configuring the acceleration sensor in multiple layers having first and second substrates to form components through first and second masking patterns, thereby forming a flexible beam having a shallow etching depth and locating a piezo element at the optimum position.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An acceleration sensor comprising:
a mass;
a flexible beam on which an electrode or a piezoresistive element is disposed and the mass is coupled; and
a support part connecting to and supporting the flexible beam and having therein a stress isolating slit facing the mass,
wherein the mass, the flexible beam and the support part are formed by coupling first and second substrates, wherein the first substrate has a first masking pattern formed thereon corresponding to the flexible beam, the mass and the support part and the second substrate has a second masking pattern formed thereon corresponding to the mass and the support part.

2. The acceleration sensor as set forth in claim 1, wherein the support part includes therein a stress isolating beam by the presence of the stress isolating slit, wherein the stress isolating beam is formed with the first substrate.

3. The acceleration sensor as set forth in claim 2, wherein the stress isolating beam includes:
a membrane part connected to the flexible beam; and
a stress isolating part perpendicularly connected to the membrane part.

4. The acceleration sensor as set forth in claim 3, wherein a coupling portion of the stress isolating part coupled with the membrane part has smaller area than the membrane part.

5. The acceleration sensor as set forth in claim 3, wherein the stress isolating part includes:
a beam part perpendicularly coupled with the membrane part; and
a protruding part protruding from the beam part toward the flexible beam.

6. The acceleration sensor as set forth in claim 1, wherein the flexible beam is formed with the first substrate.

7. The acceleration sensor as set forth in claim 1, wherein the mass includes:
a first mass formed with the first substrate; and
a second mass formed with the second substrate.

8. The acceleration sensor as set forth in claim 7, wherein the first masking pattern is formed on a surface of the first mass facing the second mass, and the second masking pattern is formed on the second mass.

9. The acceleration sensor as set forth in claim 8, wherein the first masking pattern is larger than the second masking pattern.

10. The acceleration sensor as set forth in claim 1, wherein the support part includes:
a first support part formed with the first substrate; and
a second support part formed with the second substrate.

11. The acceleration sensor as set forth in claim 10, wherein the first masking pattern is formed between the first support part and the second support part, and the second masking pattern is formed on the second support part.

12. The acceleration sensor as set forth in claim 11, wherein the first masking pattern is larger than the second masking pattern.

13. The acceleration sensor as set forth in claim 11, wherein the second support part has smaller area than the first support part.

14. The acceleration sensor as set forth in claim 1, wherein the first masking pattern faces the second substrate.

15. The acceleration sensor as set forth in claim 1, further comprising a lower cover coupled with one surface of the support part, wherein the second masking pattern faces the lower cover.

16. An acceleration sensor comprising:
a mass;
a flexible beam on which an electrode or a piezoresistive element is disposed and the mass is coupled; and
a support part connecting to and supporting the flexible beam and having therein a stress isolating slit facing the mass,
wherein the mass, the flexible beam and the support part are formed by coupling first and second substrates, wherein the first substrate has a first masking pattern formed thereon corresponding to the flexible beam, the mass and the support part.

17. The acceleration sensor as set forth in claim 16, wherein the support part includes therein a stress isolating beam by the presence of the stress isolating slit, wherein the stress isolating beam is formed with the first substrate.

18. The acceleration sensor as set forth in claim 16, wherein the flexible beam is formed with the first substrate.

19. The acceleration sensor as set forth in claim 16, wherein the mass includes:
a first mass formed with the first substrate; and
a second mass formed with the second substrate.

20. The acceleration sensor as set forth in claim 19, wherein the first masking pattern is formed between the first mass and the second mass, wherein the first mass is larger area than the second mass.

21. The acceleration sensor as set forth in claim 16, wherein the support part includes:
a first support part formed with the first substrate; and
a second support part formed with the second substrate,
wherein the first masking pattern is formed between the first support part and the second support part, wherein the first support part has larger area than the second support part.
